(19) United States
(12) Patent Application Publication
(10) Pub. No.: US 2016/0172585 A1
(43) Pub. Date: Jun. 16, 2016

(54) AN IMPROVED METHOD TO MAKE OF FABRICATING IC/MRAM USING OXYGEN ION IMPLANTATION

(71) Applicant: T3Memory, Inc., Fremont, CA (US)

(72) Inventor: Yimin Guo, San Jose, CA (US)

(73) Assignee: T3Memory, Inc., Fremont, CA (US)

(21) Appl. No.: 15/047,647

(22) Filed: Feb. 19, 2016

Related U.S. Application Data
(62) Division of application No. 14/273,501, filed on May 8, 2014, now abandoned.

(51) Int. Cl. H01L 43/12; H01L 43/10

(52) U.S. Cl. CPC H01L 43/12; H01L 43/10

(57) ABSTRACT

A method to make magnetic random access memory (MRAM), in particular, perpendicular spin transfer torque MRAM or p-STT-MRAIVI is provided. Electrically isolated memory cell is formed by ion implantation instead of etching and dielectric refill. Oxygen ion implantation is used to convert the photolithography exposed areas into metal oxide dielectric matrix. An ultrathin single-layer or multiple-layer of oxygen-getter, selected from Mg, Zr, Y, Th, Ti, Al, Ba is inserted into the active magnetic memory layer in addition to putting a thicker such material above and below the memory layer to effectively capture the impinged oxygen ions. Oxygen is further confined within the core device layer by adding oxygen stopping layer below the bottom oxygen-getter. After a high temperature anneal, a uniformly distributed and electrically insulated metal oxide dielectric is formed across the middle device layer outside the photolithography protected device area, thus forming MRAM cell without any physical deformation and damage at the device boundary.

### RELATED APPLICATIONS

This application is a divisional application due to a restriction requirement on Application No. 14/273,501. This application seeks priority to U.S. Utility Patent Application No. 14/273,501 filed on May 8, 2014 and U. S. Provisional Patent Application No. 61,825,102 filed on May 20, 2013; the entire contents of each of which are incorporated herein by reference.

### BACKGROUND OF THE INVENTION

1. Field of the Invention

This invention relates generally to spin-electronic devices, more particularly to a magnetic random access memory and a method to make the same using oxygen ion implantation.

2. Description of the Related Art

Magnetoresistive elements having magnetic tunnel junctions (also called MTJs) have been used as magnetic sensing elements for years. In recent years, magnetic random access memories (hereinafter referred to as MRAMs) using the magnetoresistive effect of MTJ have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed layer that is located on the opposite side from the recording layer and maintains a predetermined magnetization direction.

As a write method to be used in such magnetoresistive elements, there has been suggested a write method (spin torque transfer switching technique) using spin momentum transfers. According to this method, the magnetization direction of a recording layer is reversed by applying a spin-polarized current to the magnetoresistive element. Furthermore, as the volume of the magnetic layer forming the recording layer is smaller, the injected spin-polarized current to write or switch can be also smaller. Accordingly, this method is expected to be a write method that can achieve both device miniaturization and lower currents.

Further, as in a so-called perpendicular MTJ element, both two magnetization films have easy axis of magnetization in a direction perpendicular to the film plane due to their strong magnetic crystalline anisotropy, shape anisotropies are not used, and accordingly, the device shape can be made smaller than that of an in-plane magnetization type. Also, variance in the easy axis of magnetization can be made smaller. Accordingly, by using a material having a large magnetic crystalline anisotropy, both miniaturization and lower currents can be expected to be achieved while a thermal disturbance resistance is maintained.

There has been a known technique for achieving a high MR ratio in a perpendicular magnetoresistive element by forming a crystallization acceleration film that accelerates crystallization and is in contact with an interfacial magnetic film having an amorphous structure. As the crystallization acceleration film is formed, crystallization is accelerated from the tunnel barrier layer side, and the interfaces with the tunnel barrier layer and the interfacial magnetic film are matched to each other. By using this technique, a high MR ratio can be achieved. However, where a MTJ is formed as a device of a perpendicular magnetization type, the materials of the recording layer typically used in an in-plane MTJ for both high MR and low damping constant as required by low write current application normally don't have enough magnetic crystalline anisotropy to achieve thermally stable perpendicular magnetization against its demagnetization field. In order to obtain perpendicular magnetization with enough thermal stability, the recording layer has to be ferromagnetic coupled to additional perpendicular magnetization layer, such as TbCoFe, or CoPt, or multilayer such as (Co/Pt)n, to obtain enough perpendicular anisotropy. Doing so, reduction in write current becomes difficult due to the fact that damping constant increases from the additional perpendicular magnetization layer and its associated seed layer for crystal matching and material diffusion during the heat treatment in the device manufacturing process.

In a spin-injection MRAM using a perpendicular magnetization film, a write current is proportional to the perpendicular anisotropy, the damping constant and inversely proportional to a spin polarization, and increases in proportional to a square of an area size. Therefore, reduction of the damping constant, increase of the spin polarization and reduction of an area size are mandatory technologies to reduce the write current.

Besides a write current, the stability of the magnetic orientation in a MRAM cell as another critical parameter has to be kept high enough for a good data retention, and is typically characterized by the so-called thermal factor which is proportional to the perpendicular anisotropy as well as the volume of the recording layer cell size. Although a high perpendicular anisotropy is preferred in term of a high thermal disturbance resistance, an increased write current is expected as a cost.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the meantime, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus reversing the direction of magnetization of the recording layer in MTJ. Majorities of cell-to-cell variations come from the MTJ cell patterning process.

The MTJ patterning process becomes one of the most challenging aspects of manufacturing. Conventional techniques utilized to pattern small dimensions in a chip, such as ion milling etching (IBE) or reactive ion etching (RIE), having been less than satisfactory when applied to magnetic tunnel junction stacks used for MRAM. In most cases when these techniques are used, it is very difficult or almost impossible to cleanly remove etched materials without partial damages to magnetic tunnel junction properties and electric current shunting. In a RIE etching of magnetic material, physical sputtering is still the major component which unavoidable results in the formation of re-deposited residues that can short circuit the junctions of the MTJ or create shunting channel of the MTJ, yielding high resistance variations and serious reliability issues.

Another problem of conventional patterning techniques is the degradation of the recording layer and reference layer in the MTJ, due to corrosion caused by chemical residue remaining after etching. Exposure to reactive gases during refilling deposition of dielectrics such as silicon dioxide or silicon nitride after the MTJ etching can also cause corrosion. After refilling of dielectric material, a chemical mechanic polishing process is required to smooth out the top surface for bit line fabrication, which introduces a big manufacturing challenging as well as high cost and further corrosion.

Thus, it is desirable to provide a greatly improved method or innovative method that enables well-controllable and low cost fabrication in MTJ patterning while eliminating damage, degradation and corrosion.

The conventional fabrication method to form STT-MRAM is by etching and dielectric refilling. Due to a weaker ion bombardment during etch at the lower portion of the MTJ pillar; the sensor profile is typically sloped with narrow top and wide bottom. As the result, the formed sensor size cannot be made small enough to reduce the write current to switch the memory layer. Also, due to the non-volatile nature of the etched magnetic materials, often the etched sensor edge got damaged with electrical shorting across the MgO barrier.

In our earlier invention (Patent application No. 14,251,576), we use a method of fabricating IC/MRAM devices by forming an oxygen getter layer atop an active device layer (ADL), such as an MTJ, of IC/MRAM and another oxygen getter layer (OGL) below the ADL and by employing oxygen ion implantation (OH) adding oxygen ions into areas exposed by photolithography patterning thus fabricating IC/MRAM devices especially pSTT-MRAM devices. A typical film stack contains six core layers (FIG. 1): an ion implantation stopping layer (IISL) (110) at the bottom, two oxygen getters (120 & 140) sandwiching the middle ADL (130), an ion-capping layer (ICL) (150), and an ion-mask layer (IML) (160).

### BRIEF SUMMARY OF THE PRESENT INVENTION

The present invention is about an improved method, over prior inventions, of fabricating integrated circuit (IC) device(s), especially magnetic random access memory (MRAM) device(s), in particular, perpendicular spin transfer torque MRAM or p-STT-MRAM device(s). Electrical isolation for IC/MRAM device(s) or cells is formed by ion implantation instead of etching and dielectric refilling. Oxygen ion implantation is used to convert the photolithography exposed areas into metal oxide dielectric matrix. An ultrathin single-layer or multiple-layer(s) of oxygen-getter, made of one or more of Mg, Zr, Y, Th, Ti, Al, and Ba, or their alloy, is/are formed to be in between sub-layers of an ADL, such as an MTJ, of active IC/MRAM device(s) especially pSTT-MRAM devices in addition to making a relatively thicker OGLs above and below ADLs, such as MTJs, to effectively capture the impinged oxygen ions. Oxygen is further confined within the core device layer by adding oxygen stopping layer below the bottom oxygen-getter. After a high temperature anneal, a uniformly distributed and electrically insulated metal oxide dielectric is formed across the middle device layer outside the photolithography protected device area, thus forming IC/MRAM cell without any physical deformation and damage at the device boundary.

### BRIEF DESCRIPTION OF THE DRAWINGS

FIG. 1 Prior art (our early patent application).

FIG. 2 For fabricating an MRAM device with an improved efficiency and quality, an OGL (235) is made in between the sub-layers of an ADL (230) of an MRAM device in present invention.

FIG. 2a A conventional ADL (230) has no OGL inside for fabrication.

FIG. 2b For fabricating an MRAM device with an improved efficiency and quality, an OGL (235) is made in between the sub-layers of an ADL (230) in present invention.

FIG. 2c For fabricating an MRAM device with an improved efficiency and quality, two OGLs (235) or more are made in between the sub-layers of an ADL (230) in present invention.

FIG. 3 Ion mask is formed after photolithography patterning and etch.

FIG. 4 Oxygen ions are implanted into the desired region.

FIG. 5 Ion capping layer is removed from the exposed region.

FIG. 6 Device after dielectric refill and CMP.

FIG. 7 Device after a top metallic lead is formed.

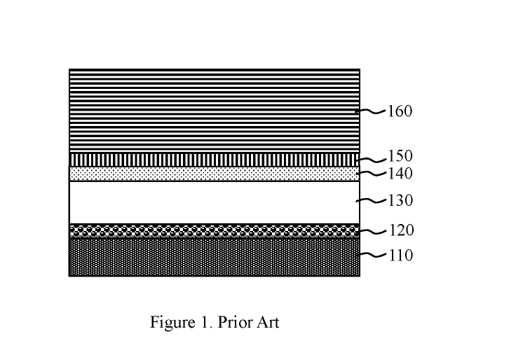

### DETAILED DESCRIPTION OF THE INVENTION

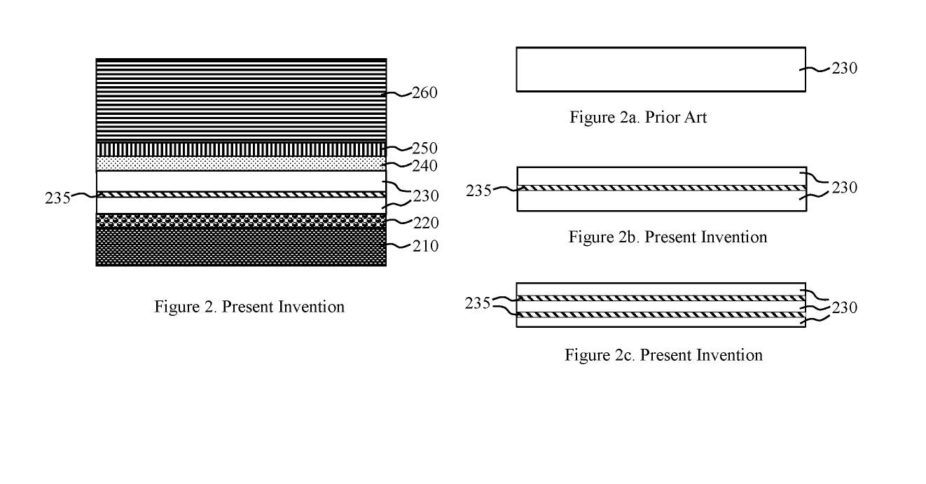

Similar to the earlier invention, our memory device still contains five core film stacks (FIG. 2): an ion implantation stopping layer (IISL) at the bottom (210), two oxygen getter layers (OGLs) (220 & 240) sandwich the middle magnetic layer magnetic memory layer (230), an ion-capping layer (250), and an ion-mask layer (260).

To better capture the oxygen ions implanted in the memory region, thus forming a uniformly distributed metal oxide dielectric (230 in FIG. 2) in the photolithography exposed area outside the device, we add an ultrathin oxygen-getter layer (235 in FIG. 2) into the middle magnetic layer. Such an OGL is selected from Mg, Zr, Y, Th, Ti, Al, Ba, with Mg as a preferred material due to its close MgO crystalline lattice match with the memory material. The thickness of such oxygen-getter layer (OGL) must be thin enough (<3A) so that the magnetic integrity of each of these magnetic (memory and reference) layers within an active device layer (ADL) is not affected. We often call such a thin oxygen getter layer as a dusting layer. If needed, a multiple dusting layers can be added in the thickness magnetic layer (230).

The IISL (210) typically contains a heavy metal with large atomic number, selected from Hf, Ta, W, Re, Os, Ir, Pt, Au, with a thickness between 200A-1000A. Pt or Au is superior to other materials because of their resistance to oxygen oxidation. The oxygen getter layers (220 & 240) typically contain a material selected among Mg, Zr, Y, Th, Ti, Al, and Ba above and below the active device region (230) to effectively capture oxygen ions during oxygen ion implantation.

For magnetic random access memory application, Mg is preferred due to its MgO close lattice constant match with CoFe. The thickness of the oxygen getter (220, 240) is typically about 50A-100A. The device region (230), such as for perpendicular spin transfer torque memory random access memory (pSTT-MRAM), typically contains three key sub-layers: CoFeB memory layer with a thickness between 10A-30A, MgO dielectric tunneling layer with a thickness between 8-15A, and a magnetic reference layer made from a hard magnetic materials, CoPt, CoPd, CoTb, FePt, FePd, FeTb or Co/Pt, Co/Pd, Fe/Pt, FePd multilayer with a total thickness between 30A-80A. The OGL (235) can be added to the memory layer CoFeB and reference layer (CoPt) or even multiple dusting in the reference layer as long as such dusting no affect the magnetic integrity of these device layers.

The ion-capping layer (ICL) (250) has two functions: first to prevent oxygen ions backing-off during oxygen ion implantation and, second to act as a reactive ion etch (RIE) stopping layer for the formation of the top ion-mask layer (260). The ion-capping layer can be selected from Ru, Cu, Al, and Cr with a thickness between 100A-300A. The top ion-mask layer (260), in general, uses the same material as the bottom ion-stopping layer (210), such as Hf, Ta, W, Re, Os, Ir, Pt, Au. For MRAM, Ta is preferred because of its ease in CF4 RIE process during the mask formation.

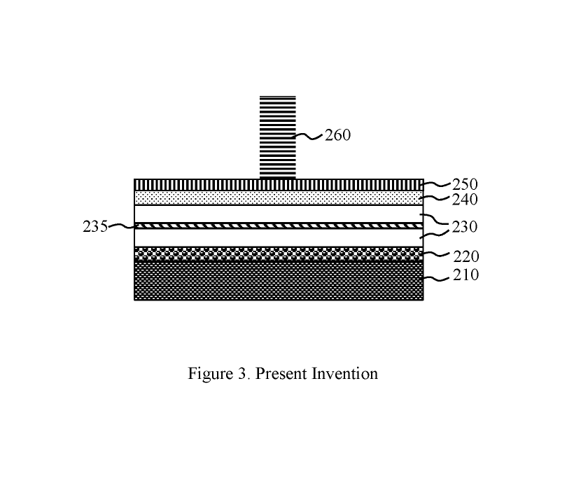

After the film deposition, a photolithography patterning is performed, which can be either one patterning or dual patterning and process (refer to our earlier dual pattern Patent application). The patterned wafer is then RIE etched to remove the exposed mask material. For Ta ion mask, a typical etchant is CF4 or CF3H or other C,F,H containing gases. The etching is stopped on top of the ion-capping layer (250). Then oxygen plasma is used to remove the remaining photoresist and etchant re-dep. The formed ion-mask layer (IML) (260) is shown in FIG. 3.

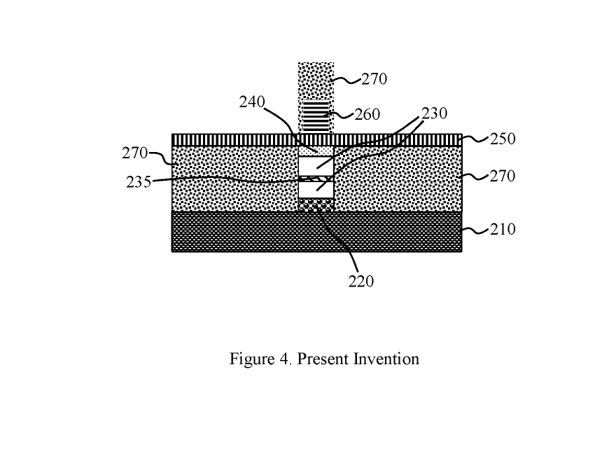

Then immediately followed by an oxygen ion implantation to add oxygen into the device layer (230). Due to presence of ion stopping layer (210), oxygen ions are mainly captured by the three oxygen getter layers (OGLs) (220, 235 & 240) redistributed into the active device layer (ADL) (230) forming a new metal oxide dielectric layer (270) with an uniform oxygen re-distribution across it after a high temperature anneal. In the meantime, the top portion of the ion-mask layer (260) is also oxidized as shown in FIG. 4.

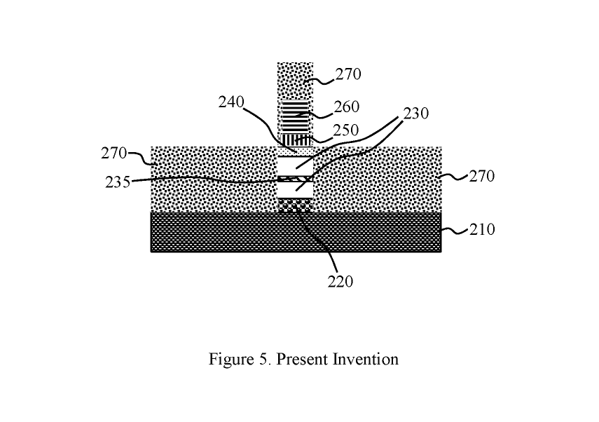

Then an etching process is used to remove the exposed portion of the ion-capping layer (ICL) using CH3OH, or CO & NH4 to prevent electric shorting within the IC device. The etching is stopped on the top surface of oxide layer 270 (FIG. 5).

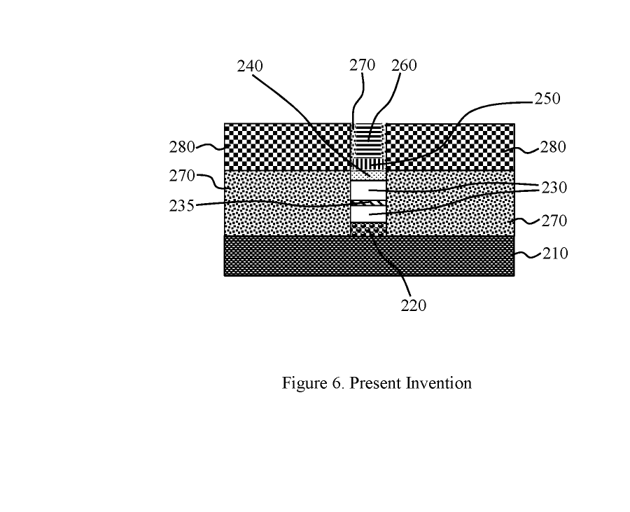

Then a dielectric SiO2, SiNx or Al2O3 layer (280) is refilled on the etched portion of the device and a chemical mechanic polishing (CMP) is used to flatten the wafer surface and also remove the top portion of the oxidized ion-mask layer (IML) (250) (see FIG. 6).

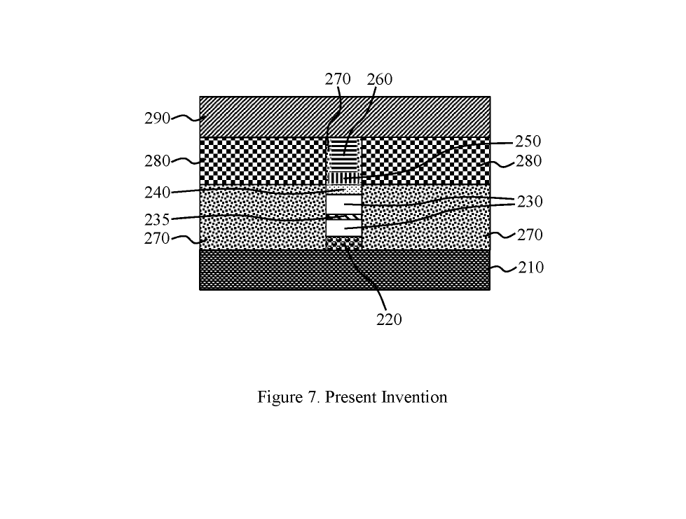

Then a top metallic film stack, i.e., electrode layer, (290) is deposited and subsequently patterned to form top electrode (FIG. 7), which can be a single metallic layer of Ru, Cu, Al or alloy of them or sandwiched between two Ta layers, with a thickness of 500 to 1000A.

The wafer is finally annealed at high temperature between 250C and 500C for a time between 30 sec and 30 minutes to activate the oxygen-metallic bonding for form metal oxide electrically insulating dielectric matrix and also to repair the damage from oxygen ion implantation.

1. An improved method of fabricating integrated circuit (IC) device(s) especially perpendicular spin torque transfer magnetic random access memory (pSTT-MRAM) device(s), using oxygen ion implantation (OII), comprising making an ion implantation stopping layer (IISL);
making an oxygen getter layer (OGL) atop the IISL;
making an active device layer (ADL) atop the OGL, further comprising
(a) making a sub-ADL;
(b) making an OGL atop the sub-ADL;
(c) repeat step (a) followed by step (b) for zero (0) or more repetitions atop the upmost OGL in process; and
(d) making an sub-ADL atop the upmost OGL in process
making an OGL atop the ADL;
making an ion-capping layer (ICL) atop the upmost OGL in process;
making one or more ion-mask layer(s) (IML);
patterning the IML;
employing OII on device(s) in process using the patterned IML as mask(s);
patterning the ICL and filling the patterned ICL;
making an electrode layer atop the filled ICL; and
heating the IC device(s) wafer.

2. The method of claim 1, wherein making a IISL comprising making a layer using one or more of Ta, Hf, W, Re, Os, Ir, Pt, and Au, or their alloy, with a total thickness between 200A to 500A, preferably Pt or Au for their superior oxidation resistance.

3. The method of claim 1, wherein making an OGL atop an IISL or atop an ADL comprising making a layer using one or more of Mg, Zr, Y, Th, Ti, Al, and Ba, or their alloy, with a thickness between 20A and 100A, preferably Mg for making MRAM device(s) due to that MgO lattice closely matches with CoFe lattice in MRAM.

4. The method of claim 1, wherein making an ADL comprising making sub-ADL(s) of one or more CoFeB memory layer(s) with a total thickness between 10A and 30A, a MgO dielectric tunneling layer with a thickness between 8A and 15A, sub-ADL(s) of one or more magnetic reference layer(s) of one or more of CoPt, CoPd, CoTb, FePt, FePd, FeTb or Co/Pt, Co/Pd, Fe/Pt, FePd layer or multilayer with a total thickness between 30A and 80A, and OGLs in between sub-ADLs, with total two or more sub-ADLs and one or more OGLs.

5. The method of claim 1, wherein making an OGL within an ADL comprising making a thin layer of one or more of Mg, Zr, Y, Th, Ti, Al, and Ba, or their alloy, with a total thickness, such as 3A or less, that such an OGL does not negatively affect the magnetic integrity of the ADL.

6. The method of claim 1, wherein making an ICL comprising making a layer of one or more of Ru, Cu, Al, and Cr, or their alloy, with a total thickness between 100A and 300A, preferably Ru.

7. The method of claim 1, wherein making an IML comprising making a layer of Ta.

8. The method of claim 1, wherein patterning the IML comprising photolithographing and etching.

9. The method of claim 28, wherein etching the IML comprising etching using one or more gases containing CF4 or CF3H or another mixture of C, F, and that is stopped on top of the ion-capping layer followed by removing the remained photoresist and redep by oxygen burning.

10. The method of claim 1, wherein employing OII on device(s) in process using the patterned IML as mask(s) comprising oxygen ion implantation with appropriate ions dose and implanting energy to impinge the oxygen ions into the areas on an IC/MRAM wafer according to the pattern of the patterned mask(s), whereby impinged oxygen ions are captured or absorbed by all OGLs as the impinged oxygen ions are enclosed within device(s) in process by the IISL with its oxidization resistance capability.

11. The method of claim 1, wherein patterning the ICL further comprising etching out the exposed ICL using CH3OH, or a mixture of CO and NH4 as etchant gas.

12. The method of claim 1, wherein filing patterned ICL comprising filling its etched out areas with dielectrics of one or more of SiO2, SiNx, or AlOx dielectrics followed by chemical-mechanical-polishing (CMP) to flatten the surface and remove the top portion of the oxidized ion-mask.

13. The method of claim 1, wherein making an electrode layer comprising making a metallic layer of one or more of Ru, Cu, and Al, or alloy of them, or sandwiched between two Ta layers, Ta/Ru/Ta or Ta/Cu&Al alloy/Ta, with a total thickness of 500 to 1000A.

14. The method of claim 1, wherein making an electrode layer further comprising patterning it with etching to form electrode line(s).

15. The method of claim 1, wherein heating the device(s) wafer comprising annealing it with temperature between 250C and 500C for from 30 seconds to 30 minutes to activate the metal-oxide bonding and to repair the device damage, if any, possibly caused by the process of oxygen ion implantation.
